(19) United States
(12) Patent Application Publication
(10) Pub. No.: US 2024/0321687 A1
(43) Pub. Date: Sep. 26, 2024

(54) BACKSIDE DECOUPLING CAPACITOR INTEGRATION WITH BACKSIDE CONTACT

(71) Applicant: International Business Machines Corporation, Armonk, NY (US)

(72) Inventors: Ruilong Xie, Niskayuna, NY (US); Nicholas Anthony Lanzillo, Wynantskill, NY (US); Lawrence A. Clevenger, Saratoga Springs, NY (US); Huai Huang, Clifton Park, NY (US); Hosadurga Shobha, Niskayuna, NY (US)

(21) Appl. No.: 18/186,236

(22) Filed: Mar. 20, 2023

(51) Int. Cl. H01L 23/48; H01L 21/8238; H01L 27/092; H01L 29/06; H01L 29/66; H01L 29/775; H01L 29/786; H01L 29/94

(52) U.S. Cl. CPC H01L 23/481; H01L 21/823807; H01L 21/823871; H01L 27/092; H01L 29/0673; H01L 29/66439; H01L 29/66545; H01L 29/775; H01L 29/78696; H01L 29/945

(57) ABSTRACT

Embodiments of the invention include a method for fabricating a semiconductor device and the resulting structure. First and second FETs are formed. A top surface of the semiconductor structure is bonded to a carrier wafer. The semiconductor structure is flipped. A MIM capacitor plane comprising first and second metal layers is formed. An ILD layer is formed on the MIM capacitor plane. A first trench is formed within the MIM capacitor plane and the ILD layer. Exposed portions of the first metal layer are recessed within the first trench. A second trench is formed within the MIM capacitor plane and the ILD layer. Exposed portions of the second metal layer are recessed. Dielectric spacers are formed in the recesses. A first backside contact is formed in the first trench and a second backside contact is formed in the second trench.

### BACKGROUND

The present invention relates generally to the field of semiconductor devices and fabrication, and more particularly to a metal-insulator-metal (MIM) capacitor plane beneath a logic region that includes (i) a first backside contact passing through the MIM capacitor plane shorting a backside voltage source line (V_{SS}), n-channel field-effect transistor (nFET) source/drain epitaxy, and first metal layers of the MIM capacitor plane and (ii) a second backside contact passing through the MIM capacitor plane shorting a backside voltage source line (V_{DD}), p-channel field-effect transistor (pFET) source/drain epitaxy, and second metal layers of the MIM capacitor plane.

A power delivery network is designed to provide power supply and reference voltage (e.g., V_{DD} and V_{SS}) to active devices. Traditionally, this is realized as a network of low-resistive metal wires fabricated through back end of line (BEOL) processing on the frontside of a wafer. A backside power delivery network (BPDN) moves the power distribution network to the backside of the wafer and enables direct power delivery through wider, less resistive metal lines, without electrons needing to travel through a complex BEOL stack.

A buried power rail (BPR) or backside power rail (BSPR) is a metal line construct buried below transistors, partially within a substrate and partially within a shallow trench isolation (STI) layer. Such a power rail takes the role of V_{DD} and/or V_{SS} power rails that have traditionally been implemented at the BEOL level.

A decoupling capacitor is a capacitor used to decouple (i.e., prevent electrical energy from transferring into) one part of a circuit from another. Noise caused by the other circuit elements is shunted through the capacitor, reducing its effect on the rest of the circuit.

### SUMMARY

Embodiments of the invention include a semiconductor structure that includes a first field-effect transistor (FET) and a second FET. A metal-insulator-metal (MIM) capacitor plane is beneath the first FET and the second FET, the MIM capacitor plane comprising a first metal layer and a second metal layer. The semiconductor structure further includes a backside power delivery network. A first backside contact passes through the MIM capacitor plane, where the first backside contact is electrically insulated from the first metal layer. A second backside contact passes through the MIM capacitor plane, where the second backside contact is electrically insulated from the second metal layer.

Embodiments of the invention also include a semiconductor structure that includes a first source/drain region and a second source/drain region. A MIM capacitor is plane beneath the first source/drain region and the second source/drain region, the MIM capacitor plane comprising a first metal layer and a second metal layer. A first backside contact passes through the MIM capacitor plane contacting the first source/drain region and the first metal layer. A second backside contact passes through the MIM capacitor plane contacting the second source/drain region and the second metal layer.

Embodiments of the invention include a method for fabricating a semiconductor device. The method includes forming a FET and a second FET. The method can also include bonding a top surface of the semiconductor structure to a carrier wafer. The method can also include flipping the semiconductor structure. The method can also include forming a MIM capacitor plane, the MIM capacitor plane comprising a first metal layer and a second metal layer. The method can also include forming a backside interlayer dielectric (ILD) layer on the MIM capacitor plane. The method can also include forming a first trench within the MIM capacitor plane and the backside ILD layer. The method can also include recessing exposed portions of the first metal layer within the first trench to create a first recess. The method can also include forming a second trench within the MIM capacitor plane and the backside ILD layer. The method can also include recessing exposed portions of the second metal layer within the second trench to create a second recess. The method can also include forming dielectric spacers in the first recess and the second recess. The method can also include forming a first backside contact in the first trench and a second backside contact in the second trench.

### BRIEF DESCRIPTION OF THE DRAWINGS

FIG. 1 depicts a top-down simplified view of a device, the device including a stacked field-effect transistor (FET) front end of line (FEOL) formation that includes gates, backside power rails (BSPRs), n-channel field-effect transistor (nFET) regions, and p-channel field-effect transistor (pFET) regions, in accordance with an embodiment of the present invention.

FIG. 2A depicts a cross-sectional view, along section line A of FIG. 1, FIG. 2B depicts a cross-sectional view, along section line B of FIG. 1, and FIG. 2C depicts a cross-sectional view, along section line C of FIG. 1, of a FETs upon which embodiments of the invention can be fabricated, in accordance with an embodiment of the present invention.

FIG. 3A depicts a cross-sectional view, along section line A of FIG. 1, FIG. 3B depicts a cross-sectional view, along section line B of FIG. 1, and FIG. 3C depicts a cross-sectional view, along section line C of FIG. 1, of a process of forming source/drain (S/D) contacts, a gate contact, a back end of line (BEOL) interconnect, and the bonding of the device to a carrier wafer, in accordance with an embodiment of the present invention.

FIG. 4A depicts a cross-sectional view, along section line A of FIG. 1, FIG. 4B depicts a cross-sectional view, along section line B of FIG. 1, and FIG. 4C depicts a cross-sectional view, along section line C of FIG. 1, of a process of removing the semiconductor substrate, in accordance with an embodiment of the present invention.

FIG. 5A depicts a cross-sectional view, along section line A of FIG. 1, FIG. 5B depicts a cross-sectional view, along section line B of FIG. 1, and FIG. 5C depicts a cross-sectional view, along section line C of FIG. 1, of a process of removing an etch stop layer and a semiconductor layer, in accordance with an embodiment of the present invention.

FIG. 6A depicts a cross-sectional view, along section line A of FIG. 1, FIG. 6B depicts a cross-sectional view, along section line B of FIG. 1, and FIG. 6C depicts a cross-sectional view, along section line C of FIG. 1, of a process of forming a backside interlayer dielectric (ILD), in accordance with an embodiment of the present invention.

FIG. 7A depicts a cross-sectional view, along section line A of FIG. 1, FIG. 7B depicts a cross-sectional view, along section line B of FIG. 1, and FIG. 7C depicts a cross-sectional view, along section line C of FIG. 1, of a process of forming a multiple layer metal-insulator-metal (MIM) stack, in accordance with an embodiment of the present invention.

FIG. 8A depicts a cross-sectional view, along section line A of FIG. 1, FIG. 8B depicts a cross-sectional view, along section line B of FIG. 1, and FIG. 8C depicts a cross-sectional view, along section line C of FIG. 1, of a process of forming a backside ILD and backside contact trench for the nFET, in accordance with an embodiment of the present invention.

FIG. 9A depicts a cross-sectional view, along section line A of FIG. 1, FIG. 9B depicts a cross-sectional view, along section line B of FIG. 1, and FIG. 9C depicts a cross-sectional view, along section line C of FIG. 1, of a process of selectively removing portions of a first metal from the MIM stack, in accordance with an embodiment of the present invention.

FIG. 10A depicts a cross-sectional view, along section line A of FIG. 1, FIG. 10B depicts a cross-sectional view, along section line B of FIG. 1, and FIG. 10C depicts a cross-sectional view, along section line C of FIG. 1, of a process of forming an organic planarization layer (OPL) and a backside contact trench for the pFET, followed by the removal of portions of a second metal from the MIM stack, in accordance with an embodiment of the present invention.

FIG. 11A depicts a cross-sectional view, along section line A of FIG. 1, FIG. 11B depicts a cross-sectional view, along section line B of FIG. 1, and FIG. 11C depicts a cross-sectional view, along section line C of FIG. 1, of a process of removing the OPL and forming inner spacers, in accordance with an embodiment of the present invention.

FIG. 12A depicts a cross-sectional view, along section line A of FIG. 1, FIG. 12B depicts a cross-sectional view, along section line B of FIG. 1, and FIG. 12C depicts a cross-sectional view, along section line C of FIG. 1, of a process of forming backside contacts, in accordance with an embodiment of the present invention.

FIG. 13A depicts a cross-sectional view, along section line A of FIG. 1, FIG. 13B depicts a cross-sectional view, along section line B of FIG. 1, and FIG. 13C depicts a cross-sectional view, along section line C of FIG. 1, of a process of forming a backside power rail and backside power delivery network (BSPDN), in accordance with an embodiment of the present invention.

### DETAILED DESCRIPTION

Embodiments of the present invention recognize that with backside contact and backside power delivery networks (BSPDNs), there is opportunity to integrate super large decoupling capacitors on the backside of a wafer.

Embodiments of the present invention describe an approach for fabricating a semiconductor device, the approach including forming a front end of line transistor (FEOL), back end of line (BEOL) interconnect, and carrier wafer bonding. Embodiments of the present invention further describe flipping the wafer and removing the substrate. Embodiments of the present invention further describe forming backside interlayer dielectric (ILD) and a metal-insulator-metal (MIM) stack, the MIM stack including a first metal and a second metal. Embodiments of the present invention further describe forming an n-channel field-effect transistor (nFET) direct backside contact trench that includes indenting the first metal. Embodiments of the present invention further describe forming a p-channel field-effect transistor (pFET) direct backside contact trench that includes indenting the second metal. Embodiments of the present invention further describe forming inner spacers in the indents of the first metal and the second metal and, subsequently, forming a backside contact metallization layer. Embodiments of the present invention describe an approach for forming a backside power rail and BSPDN.

Embodiments of the present invention describe a resulting semiconductor structure that includes at least a backside MIM capacitor plane underneath a logic region, where a first backside contact passes through the MIM capacitor plane, shorting a backside voltage source line (V_{SS}), nFET source/drain epitaxy, and first metal layers of the MIM capacitor plane. Embodiments of the present invention further describe that a second backside contact passes through the MIM capacitor plane, shorting a backside voltage source line (V_{DD}), pFET source/drain epitaxy, and second metal layers of the MIM capacitor plane. In some embodiments, the first metal layers and the second metal layers are made of different metals. In some embodiments of the present invention, inner spacers are formed at the sidewall of the direct backside contact to isolate the nFET direct backside contact from the first metal layers and to isolate the pFET direct backside contact from the second metal layers.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Each reference number may refer to an item individually or collectively as a group. For example, source/drain region 255 may refer to a single source drain region 255 or multiple source/drain regions 255.

The present invention will now be described in detail with reference to the Figures.

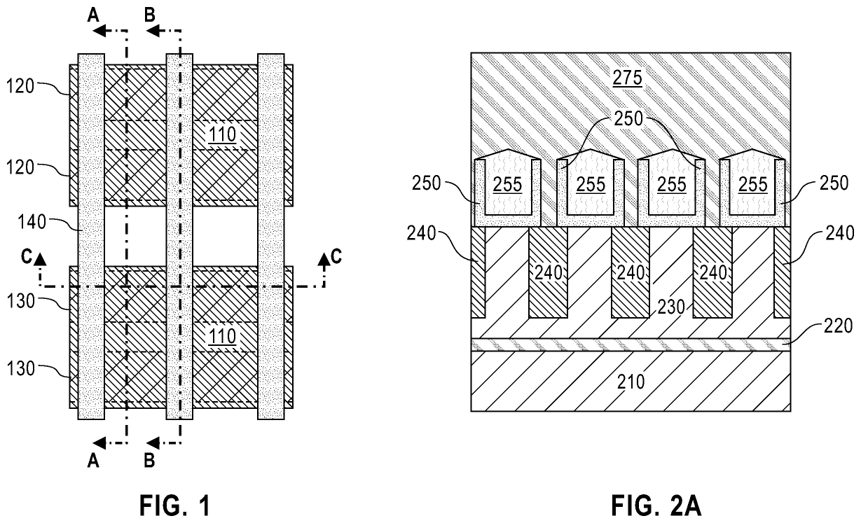

FIG. 1 is a simplified depiction of the device and is provided primarily to establish a frame of reference for the presence of the cross-sectional views of the other Figures. Accordingly, many objects and features that are present in the cross-sectional views are not depicted in FIG. 1. Further, FIG. 1 is a top-view. FIG. 1 generally shows the location of the gates 140 (e.g., gate 285 of FIGS. 1C-13C), backside power rail (BSPR) 110, nFETs 120, and pFETs 130.

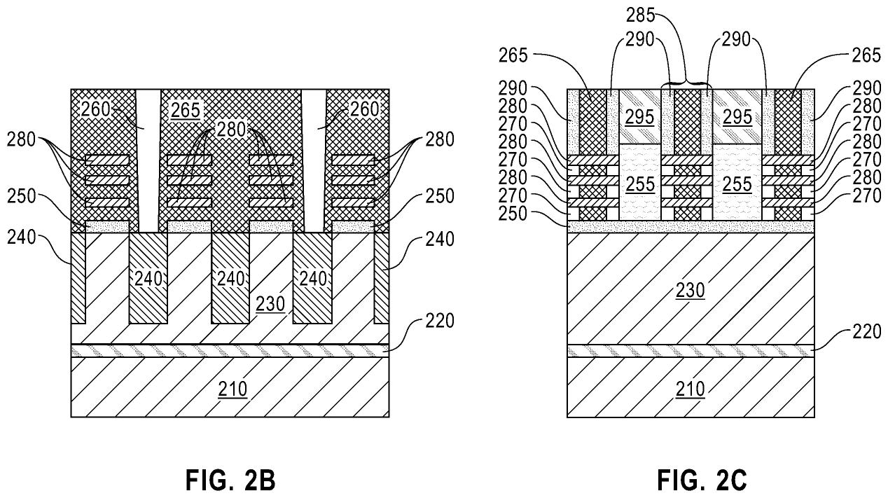

FIG. 2A depicts a cross-sectional view, of a device at an early stage in the method of forming the device, along section line A of FIG. 1, FIG. 2B depicts a cross-sectional view along section line B of FIG. 1, and FIG. 2C depicts a cross-sectional view along section line C of FIG. 1.

The semiconductor structure of FIGS. 2A-2C includes a semiconductor substrate upon which embodiments of the invention can be fabricated.

Semiconductor substrate 210 may be composed of a silicon containing material. Silicon containing materials include, but are not limited to, silicon, single crystal silicon, polycrystalline silicon, SiGe, single crystal SiGe, polycrystalline SiGe, or silicon doped with carbon (C), amorphous silicon, and combinations and multi-layers thereof. Semiconductor substrate 210 can also be composed of other semiconductor materials, such as germanium (Ge), and compound semiconductor substrates, such as type III/V semiconductor substrates, e.g., gallium arsenide (GaAs). In general, semiconductor substrate 210 is a smooth surface substrate. In some embodiments (not shown), semiconductor substrate 210 can be a partially processed complementary metal-oxide semiconductor (CMOS) integrated wafer with transistors and wiring levels or gate electrodes embedded beneath the surface.

Etch stop layer 220 is present above semiconductor substrate 210. Etch stop layer 220 acts as a layer used to define the structure thickness by stopping the etch when the etch stop layer is reached. Etch stop layer 220 may be composed of, for example, silicon dioxide, or epitaxy SiGe.

Semiconductor layer 230 is present above etch stop layer 220. Semiconductor layer 230 may be composed of a silicon containing material such as the silicon containing materials discussed with respect to semiconductor substrate 210.

Shallow trench isolation (STI) layer 240 may be formed by patterning a hardmask layer (not shown) using lithography and etching such that top surfaces of portions of semiconductor layer 230 are exposed corresponding to locations where trenches for STI layer 240 are desired. Accordingly, the hardmask layer is patterned such that semiconductor layer 230 is exposed at desired trench locations for STI layer 240.

Physically exposed portions of semiconductor layer 230 are removed. The removing of portions of semiconductor layer 230 can be performed utilizing an anisotropic etching process such as, for example, reactive ion etching (RIE). Portions of semiconductor layer 230 remain beneath the hardmask.

FETs are depicted in FIGS. 2A-2C and may generally be formed as described herein.

In the depicted embodiment, a semiconductor material stack (sacrificial semiconductor material layer, semiconductor channel material layer 280) is formed upon a bottom sacrificial layer. The semiconductor material stack includes vertically aligned alternating layers of sacrificial semiconductor material layer and semiconductor channel material layer 280. The semiconductor material stack is sequentially formed upon the bottom sacrificial layer. As mentioned above, the semiconductor material stack includes sacrificial semiconductor material layers and semiconductor channel material layers 280, which alternate one atop the other. In FIGS. 2A-2C, and only by way of one example, the semiconductor material stack includes three layers of sacrificial semiconductor material layer and three layers of semiconductor channel material layer 280. The semiconductor material stacks that can be employed in embodiments of the present invention are not limited to the specific embodiment illustrated in FIGS. 2A-2C. Instead, the semiconductor material stack can include any number of sacrificial semiconductor material layers and semiconductor channel material layers 280. The semiconductor material stack is used to provide a gate-all-around device that includes vertically stacked semiconductor channel material nanosheets for a pFET and/or nFET device. It should be noted that while the depicted embodiment uses a nanosheet device, the device can be any kind of non-vertical or horizontal device, such as, for example, fin field-effect transistor (FinFET), planar FET, nanowire, or extremely-thin silicon-on-insulator (ETSOI).

Each sacrificial semiconductor material layer is composed of a first semiconductor material which differs in composition from the bottom sacrificial layer or semiconductor channel material layer 280. In one embodiment, each sacrificial semiconductor material layer is composed of silicon germanium with Ge % 20% to 35%. The bottom sacrificial layer is composed of silicon germanium with Ge % 50% to 70%. The semiconductor channel material layer 280 is composed of silicon. The bottom sacrificial layer, sacrificial semiconductor material layer and semiconductor channel material layer 280, can be formed utilizing epitaxial growth from semiconductor layer 230.

Following epitaxial growth of the topmost layer of the semiconductor material stack (bottom sacrificial layer, sacrificial semiconductor material layer, semiconductor channel material layer 280) a patterning process may be used to provide the semiconductor material stack. Patterning may be achieved by lithography and etching as is well known to those skilled in the art.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. The epitaxial growth the first and second semiconductor materials that provide the sacrificial semiconductor material layers and the semiconductor channel material layers 280, respectively, can be performed utilizing any well-known precursor gas or gas mixture. Carrier gases like hydrogen, nitrogen, helium and argon can be used.

The sacrificial semiconductor material layers that constitute the semiconductor material stack may have a thickness from five nm to twenty nm, while the semiconductor channel material layers 280 that constitute the semiconductor material stack may have a thickness from six nm to twelve nm. Each sacrificial semiconductor material layer may have a thickness that is the same as, or different from, a thickness of each semiconductor channel material layer 280. In an embodiment, each sacrificial semiconductor material layer has an identical thickness. In an embodiment, each semiconductor channel material layer 280 has an identical thickness.

A sacrificial gate structure may be formed. Each sacrificial gate structure is located on a first side and a second side of the semiconductor material stack (bottom sacrificial layer, sacrificial semiconductor material layer, semiconductor channel material layer 280) and spans across a topmost surface of a portion of the semiconductor material stack (bottom sacrificial layer, sacrificial semiconductor material layer, semiconductor channel material layer 280). Each sacrificial gate structure thus straddles over a portion of the semiconductor material stack (bottom sacrificial layer, sacrificial semiconductor material layer, semiconductor channel material layer 280). After, the bottom sacrificial layer is selectively removed, followed by conformal dielectric deposition and anisotropic etch to form bottom dielectric isolation (BDI) layer 250 and gate spacer 290. The dielectric spacer material layer is present on sidewalls of each sacrificial gate structure; the dielectric spacer material layer thus also straddles over the semiconductor material stack at source/drain region 255.

Each sacrificial gate structure may include a single sacrificial material portion or a stack of two or more sacrificial material portions (i.e., at least one sacrificial material portion). In one embodiment, the at least one sacrificial material portion comprises, from bottom to top, a sacrificial gate dielectric portion, a sacrificial gate portion and a sacrificial dielectric cap portion. In some embodiments, the sacrificial gate dielectric portion and/or the sacrificial dielectric cap portion can be omitted and only a sacrificial gate portion is formed. The at least one sacrificial material portion can be formed by forming a blanket layer (or layers) of a material (or various materials) and then patterning the material (or various materials) by lithography and an etch. In one embodiment, the at least one sacrificial material portion can be formed by first depositing a blanket layer of a sacrificial gate dielectric material. The sacrificial gate dielectric material can be an oxide, nitride, and/or oxynitride. In one example, the sacrificial gate dielectric material can be a high-K material having a dielectric constant greater than silicon dioxide. In some embodiments, a multilayered dielectric structure comprising different dielectric materials, e.g., silicon dioxide, and a high-K dielectric can be formed and used as the sacrificial gate portion. The sacrificial gate dielectric material can be formed by any deposition technique including, for example, chemical vapor deposition (CVD), plasma enhanced chemical vapor deposition (PECVD), physical vapor deposition (PVD), sputtering, or atomic layer deposition (ALD).

After forming the blanket layer of sacrificial gate dielectric material, a blanket layer of a sacrificial gate material can be formed on the blanket layer of sacrificial gate dielectric material. The sacrificial gate material can include any material including, for example, polysilicon, amorphous silicon, an elemental metal (e.g., tungsten, titanium, tantalum, aluminum, nickel, ruthenium, palladium and platinum), an alloy of at least two elemental metals or multilayered combinations thereof. The sacrificial gate material can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

After forming the blanket layer of sacrificial gate material, a blanket layer of a sacrificial gate cap material can be formed. The sacrificial gate cap material may include a hardmask material such as, for example, silicon dioxide and/or silicon nitride. The sacrificial gate cap material can be formed by any suitable deposition process such as, for example, chemical vapor deposition (CVD) or plasma enhanced chemical vapor deposition (PECVD).

After providing the above mentioned sacrificial material stack (or any subset of the sacrificial materials), lithography and etching can be used to pattern the sacrificial material stack (or any subset of the sacrificial materials) and to provide the at least one sacrificial gate structure. The remaining portions of the sacrificial gate dielectric material constitute a sacrificial gate dielectric portion, the remaining portions of the sacrificial gate material constitute a sacrificial gate portion, and the remaining portions of the sacrificial dielectric cap material constitute a sacrificial dielectric cap portion.

After providing the sacrificial gate structure, the bottom sacrificial layer is removed, dielectric spacer material layer 290 can be formed on exposed surfaces of each sacrificial gate structure. The dielectric spacer material layer 290 can be formed by first providing a dielectric spacer material and then etching the dielectric spacer material. One example of a dielectric spacer material that may be employed in the present application is silicon nitride. In general, the dielectric spacer material layer 290 comprises any dielectric spacer material, including, for example, a dielectric nitride, dielectric oxide, and/or dielectric oxynitride. More specifically, the dielectric spacer material layer 290 may be, for example, SiBCN, SiBN, SiOCN, SION, SiCO, or SiC. In one example, the dielectric spacer material is composed of a dielectric material such as SiO₂. The conformal deposition of dielectric spacer will also fill the cavity formed by removing the bottom sacrificial layer, forming BDI layer 250.

The dielectric spacer material that provides the dielectric spacer material layer 290 may be provided by a deposition process including, for example, ALD, chemical vapor deposition (CVD), plasma enhanced chemical vapor deposition (PECVD), or physical vapor deposition (PVD). The etch used to provide the dielectric spacer material layer may comprise a dry etching process such as, for example, reactive ion etching.

Recesses may be formed within the semiconductor material stack, creating the formation of nanosheet stacks of alternating nanosheets of sacrificial semiconductor material layers and semiconductor channel material layers 280 that are under at least one sacrificial gate structure and dielectric spacer material layer 290.

The nanosheet stack is formed by removing physically exposed portions of the semiconductor material stack (bottom sacrificial layer, sacrificial semiconductor material layer, semiconductor channel material layer 280) that are not protected by the least one sacrificial gate structure and the dielectric spacer material layer 290. In general, each recess may include the eventual location of source/drain region 255, for the semiconductor device.

The removing of the portions of the semiconductor material stack (bottom sacrificial layer, sacrificial semiconductor material layer, semiconductor channel material layer 280) not covered by the least one sacrificial gate structure and the dielectric spacer material layer 290 can be performed utilizing an anisotropic etching process such as, for example, reactive ion etching (RIE). Portions of the semiconductor material stack (bottom sacrificial layer, sacrificial semiconductor material layer, semiconductor channel material layer 280) remain beneath at least one sacrificial gate structure and the dielectric spacer material layer 290. The remaining portion of the semiconductor material stack that is present beneath the at least one sacrificial gate structure and the dielectric spacer material layer is referred to as a nanosheet stack.

Each nanosheet stack includes alternating nanosheets of remaining portions of each sacrificial semiconductor material layer and remaining portions of each semiconductor channel material layer 280. The nanosheet stack includes alternating nanosheets of remaining portions of each of sacrificial semiconductor material layer and semiconductor channel material layer 280. Each nanosheet (i.e., sacrificial semiconductor material layer or semiconductor channel material layer 280) that constitutes the nanosheet stack has a thickness as mentioned above for the individual sacrificial semiconductor material layers and semiconductor channel material layers 280, and a width from 30 nm to 200 nm. In some embodiments, the sidewalls of each sacrificial semiconductor material layer are vertically aligned to sidewalls of each semiconductor channel material layer 280, and the vertically aligned sidewalls of the nanosheet stack are vertically aligned to an outmost sidewall of the dielectric spacer material layer.

The sacrificial semiconductor material layer is recessed and inner spacer 270 is formed. Each recessed sacrificial semiconductor material layer has a width that is less than the original width of each sacrificial semiconductor material layer. The recessing of each sacrificial semiconductor material layer provides a gap between each neighboring pair of semiconductor channel material layer 280 within a given nanosheet stack. The recessing of each sacrificial semiconductor material layer may be performed utilizing a lateral etching process that is selective in removing physically exposed end portions of each sacrificial semiconductor material layer relative to each semiconductor channel material layer 280.

The additional dielectric spacer material that is added can be compositionally the same as the dielectric spacer material layer mentioned above. In one example, the additional dielectric spacer material and the dielectric spacer material layer are both composed of silicon nitride. For clarity, the additional dielectric spacer material and the dielectric spacer material layer can now be referred to as inner spacer 270. The inner spacer 270 is formed by a conformal dielectric liner deposition followed by isotropic etching back the deposited liner.

Source/drain region 255 is formed by epitaxial growth of a semiconductor material on physically exposed sidewalls of each semiconductor channel material layer 280. The source/drain region 255 has a bottommost surface that directly contacts a topmost surface of BDI layer 250.

Each source/drain region 255 includes a semiconductor material and a dopant. The semiconductor material that provides each source/drain region 255 can be selected from one of the semiconductor materials mentioned above for the semiconductor substrate 210. In some embodiments, the semiconductor material that provides each source/drain region 255 may comprise a same semiconductor material as that which provides semiconductor channel material layer 280. In other embodiments, the semiconductor material that provides each source/drain region 255 may comprise a different semiconductor material than that which provides semiconductor channel material layer 280. For example, the semiconductor material that provides each source/drain region 255 may comprise a silicon germanium alloy, while semiconductor channel material layer 280 may comprise silicon.

The dopant that is present in each source/drain region 255 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one embodiment, the dopant that can be present in each source/drain region 255 can be introduced into the precursor gas that provides each source/drain region 255. In another embodiment, the dopant can be introduced into an intrinsic semiconductor layer by utilizing one of ion implantation or gas phase doping. In one example, each source/drain region 255 comprises a silicon germanium alloy that is doped with a p-type dopant such as, for example, boron. As mentioned above, each source/drain region 255 is formed by an epitaxial growth (or deposition) process, as is defined above.

In the embodiment depicted in FIGS. 2A-13A, the leftmost two source/drain regions 255 are dropped with an n-type dopant and the rightmost two source drain regions 255 are doped with a p-type dopant.

ILD material 275 is formed above and around each source/drain region 255. ILD material 275 may be composed of silicon dioxide, undoped silicate glass (USG), fluorosilicate glass (FSG), borophosphosilicate glass (BPSG), a spin-on low-K dielectric layer, a chemical vapor deposition (CVD) low-K dielectric layer or any combination thereof. The term “low-K” as used throughout the present application denotes a dielectric material that has a dielectric constant of less than silicon dioxide. In another embodiment, a self-planarizing material such as a spin-on glass (SOG) or a spin-on low-K dielectric material such as SiLK™ can be used as ILD material 275. The use of a self-planarizing dielectric material as ILD material 275 may avoid the need to perform a subsequent planarizing step.

In one embodiment, ILD material 275 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as ILD material 275, a planarization process or an etch back process follows the deposition of the dielectric material that provides ILD material 275. As is shown in FIGS. 2A-2C, ILD material 275 that is present atop each source/drain region 255 has a topmost surface that is coplanar to a topmost surface of dielectric spacer material layer 290.

Each sacrificial gate structure is removed to provide a gate cavity for the FET.

Next, each semiconductor channel material nanosheet (i.e., semiconductor channel material layer 280) of the FET is suspended by selectively etching each recessed sacrificial semiconductor material nanosheet relative to each semiconductor channel material nanosheet (i.e., semiconductor channel material layer 280).

Functional gate structures are formed in each gate cavity. The functional gate structure surrounds a physically exposed surface of each semiconductor channel material nanosheet (i.e., semiconductor channel material layer 170). The functional gate structure surrounds a physically exposed surface of each semiconductor channel material nanosheet (i.e., semiconductor channel material layer 280). By “functional gate structure” it is meant a permanent gate structure used to control output current (i.e., flow of carriers in the channel) of a semiconducting device through electrical or magnetic fields. The functional gate structures are referred to as replacement gate 265 in the Figures.

While not depicted, in some embodiments, a gate dielectric portion may be present that includes a gate dielectric material. Such a gate dielectric portion may be an oxide, nitride, and/or oxynitride. In one example, the gate dielectric portion can be a high-k material having a dielectric constant greater than silicon dioxide. Example high-K dielectrics include, but are not limited to, HfO2, ZrO2, La2O3, Al2O3, TiO2, SrTiO3, LaALO3, Y2O3, HfOxNy, ZrOxNy, La2OxNy, Al2OxNy, TiOxNy, SrTiOxNy, LaAlOxNy, Y2OxNy, SiON, SiNx, a silicate thereof, and an alloy thereof. Each value of x is independently from 0.5 to 3 and each value of y is independently from 0 to 2. In some embodiments, a multilayered gate dielectric structure comprising different gate dielectric materials, e.g., silicon dioxide, and a high-K gate dielectric, can be formed and used as the gate dielectric portion.

The gate dielectric material used in providing a gate dielectric portion can be formed by any deposition process including, for example, chemical vapor deposition (CVD), plasma enhanced chemical vapor deposition (PECVD), physical vapor deposition (PVD), sputtering, or atomic layer deposition. In one embodiment of the present application, the gate dielectric material used in providing a gate dielectric portion can have a thickness in a range from 1 nm to 10 nm. Other thicknesses that are lesser than, or greater than, the aforementioned thickness range can also be employed for the gate dielectric material that may provide a gate dielectric portion.

Replacement gate 265 includes a gate conductor material and a gate dielectric. The gate conductor material used in providing replacement gate 265 can include any conductive material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride, TiAlC, TiC, TiAl), an elemental metal silicide (e.g., tungsten silicide, nickel silicide, and titanium silicide), or multilayered combinations thereof. In one embodiment, replacement gate 265 may comprise an nFET gate metal. In another embodiment, replacement gate 265 may comprise a pFET gate metal. When multiple gate cavities are formed, it is possible to form a nFET in a first set of the gate cavities and wrapping around some of the semiconductor channel material nanosheet (i.e., semiconductor channel material layer 280) and a pFET in a second set of the gate cavities and wrapping around some of the semiconductor channel material nanosheet (i.e., semiconductor channel material layer 280).

The gate conductor material used in providing replacement gate 265 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes. When a metal silicide is formed, a conventional silicidation process is employed. In one embodiment, the gate conductor material used in providing replacement gate 265 can have a thickness from 5 nm to 200 nm. Other thicknesses that are lesser than, or greater than, the aforementioned thickness range can also be employed for the gate conductor material used in providing replacement gate 265.

A functional gate structure (replacement gate 265) can be formed by providing a functional gate material stack of the gate dielectric material and the gate conductor material. A planarization process may follow the formation of the functional gate material stack.

Gate cuts 260 may be patterned by conventional lithography and etch processes to isolate the gate regions at cell boundaries. Each gate cut 260 is filled with a dielectric material such as, for example, SiN or a combination of SiN and SiO2.

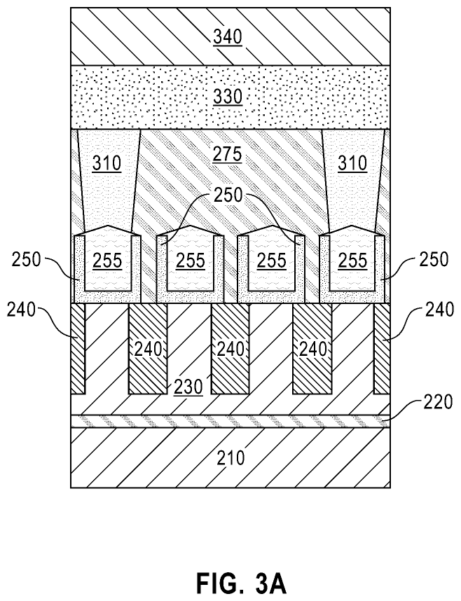

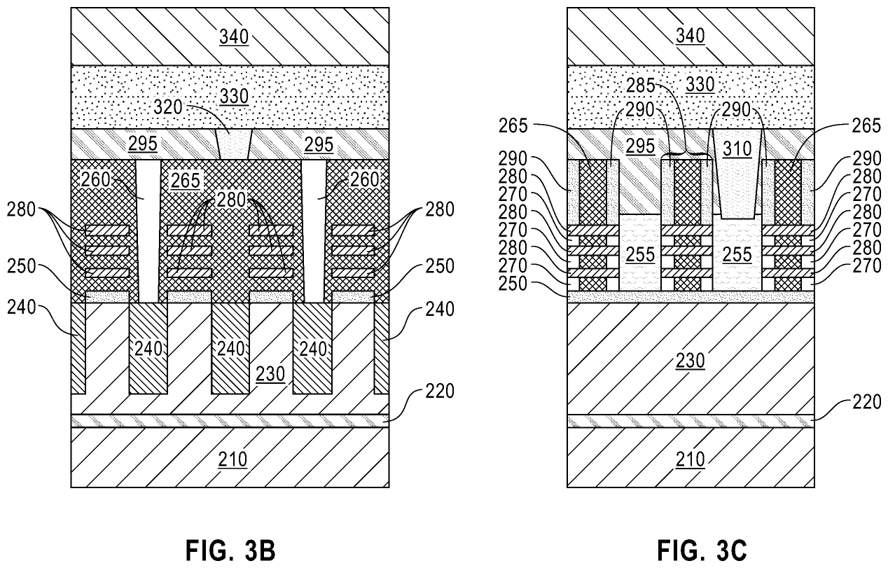

FIG. 3A depicts a cross-sectional view, of fabrication steps, along section line A of FIG. 1, FIG. 3B depicts a cross-sectional view along section line B of FIG. 1, and FIG. 3C depicts a cross-sectional view along section line C of FIG. 1. FIGS. 3A-3C depict the formation of source/drain (S/D) contacts 310, gate contact 320, BEOL interconnect 330, and the bonding of the device to carrier wafer 340.

One or more trenches may be formed by lithography and an etching process, such as reactive-ion etching (RIE), laser ablation, or any etch process which can be used to selectively remove a portion of material such as ILD material 275. A hardmask (not shown) may be patterned using photoresist to expose areas of the device where trenches are desired and the hardmask may be utilized during the etching process in the creation of the trenches. The etching process only removes portions of the device not protected by the hardmask and the etching process stops at source/drain region 255 and/or replacement gate 265.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

In general, S/D contacts 310 are formed and make contact with source/drain region 255. Gate contact 320 is formed and makes contact with replacement gate 265.

S/D contacts 310 and gate contact 320 may each be formed by metal deposition and planarization. The metal layers comprise a silicide liner, such as, for example, Ti, Ni, or NiPt, followed by adhesion metal liner, such as, for example, TiN, and a conductive metal fill, such as, for example, Co, Ru, W, or Cu.

Each S/D contact 310 and gate contact 320 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

BEOL interconnect 330 is depicted as a simple layer, rather than showing the specific interconnects. BEOL interconnect 330 may be formed according to processes known in the art such as, for example, patterning and dual damascene.

Carrier wafer 340 is a wafer that is bonded with a top surface of BEOL interconnect 330. Carrier wafer 340 may be, for example, a silicon wafer. Such bonding can be accomplished using fusion bonding (for example silicon oxide to silicon oxide) or by means of intermediate-layer bonding (for example using adhesives). A variety of bonding means may be used such as, for example, pressure bonding, for press-bonding the device to the carrier wafer 340 or a heat bonding approach for utilizing heat to bond the device to carrier wafer 340.

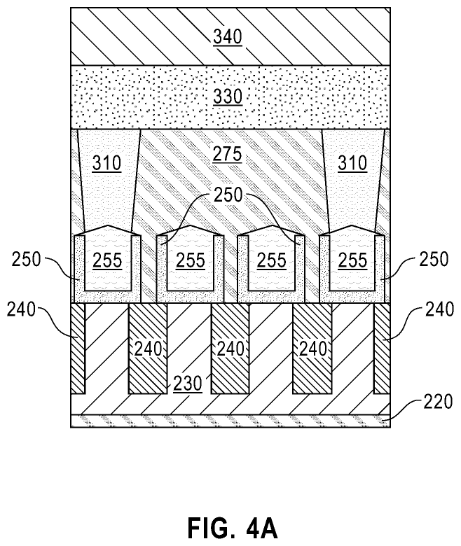

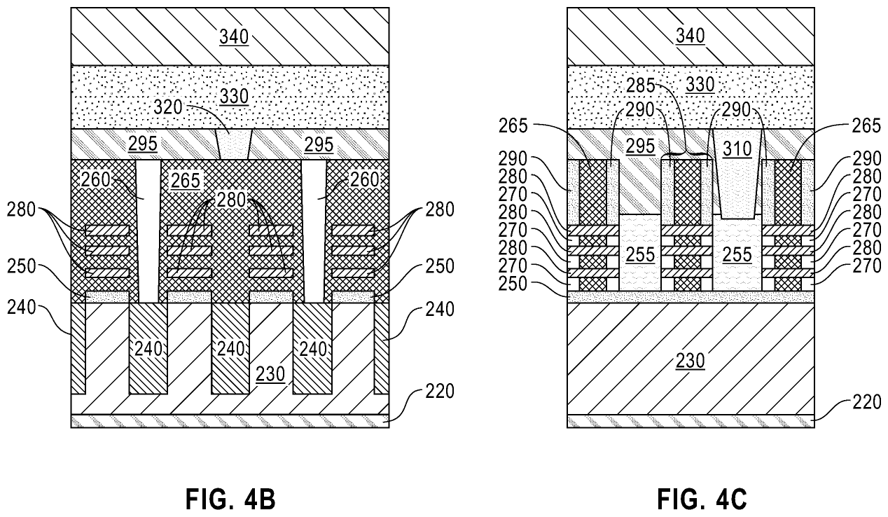

Subsequent to bonding the device to carrier wafer 340, the device is flipped upside-down such that the formation or removal of any layers occurs on what is considered to be the bottom of the device. This flip is not depicted in the Figures and, accordingly, FIGS. 4A-4C through FIGS. 13A-13C depict process steps that occur on the bottom surfaces of the device. In reality, during fabrication, these steps are performed when the device is upside-down, as compared to the depiction of FIGS. 4A-4C through FIGS. 13A-13C.

FIG. 4A depicts a cross-sectional view, of fabrication steps, along section line A of FIG. 1, FIG. 4B depicts a cross-sectional view along section line B of FIG. 1, and FIG. 4C depicts a cross-sectional view along section line C of FIG. 1. FIGS. 4A-4C depict the removal of semiconductor substrate 210.

As described above, prior to this step, the wafer containing device is flipped such that a top surface of the wafer faces downwards and the carrier wafer 340 acts as a bottom surface of the flipped device.

A combination of processes, such as wafer grinding, CMP, and/or wet/dry etch processes may be used to remove semiconductor substrate 210, stopping at etch stop layer 220.

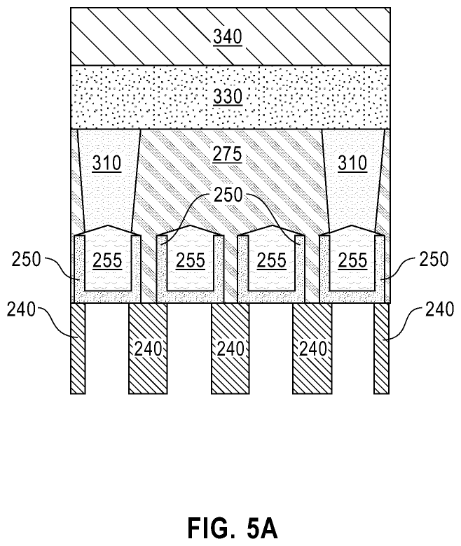

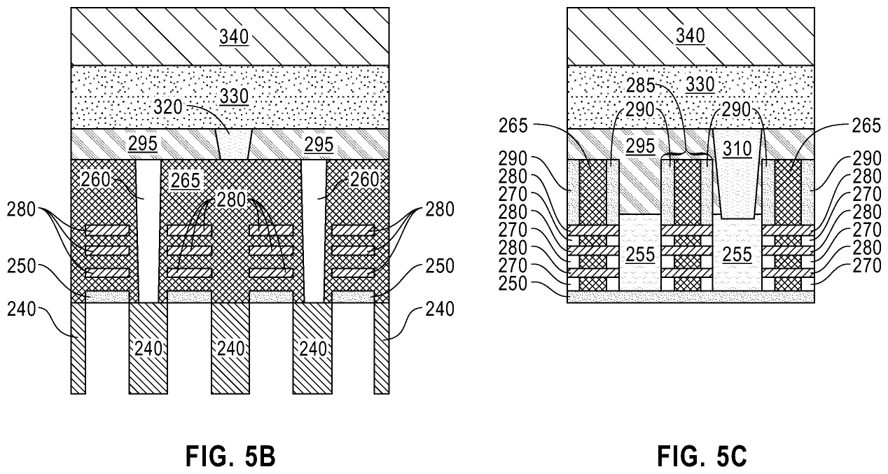

FIG. 5A depicts a cross-sectional view, of fabrication steps, along section line A of FIG. 1, FIG. 5B depicts a cross-sectional view along section line B of FIG. 1, and FIG. 5C depicts a cross-sectional view along section line C of FIG. 1. FIGS. 5A-5C depict the removal of etch stop layer 220 and semiconductor layer 230.

A selective wet or dry etch process is performed to remove etch stop layer 220.

Semiconductor layer 230 is then removed using an etching process such as RIE, wet etch, or any etch process which can be used to selectively remove a portion of material, such as the semiconductor layer 230, with respect to STI layer 240 and BDI layer 250.

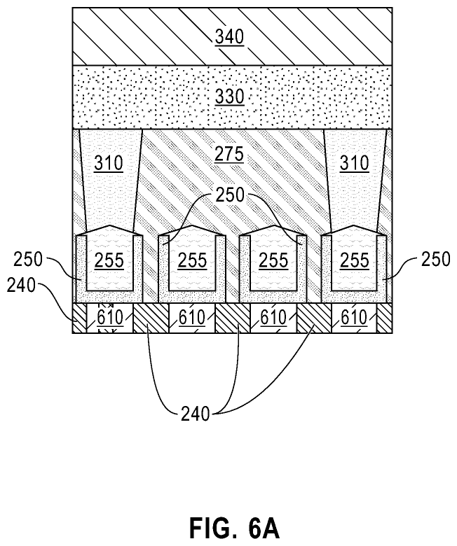

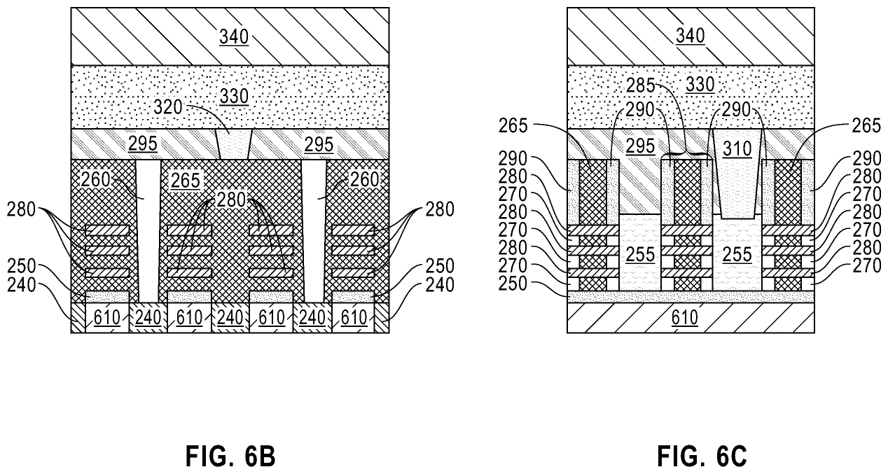

FIG. 6A depicts a cross-sectional view, of fabrication steps, along section line A of FIG. 1, FIG. 6B depicts a cross-sectional view along section line B of FIG. 1, and FIG. 6C depicts a cross-sectional view along section line C of FIG. 1. FIGS. 6A-6C depict the formation of backside ILD 610.

Backside ILD 610 material is formed below (as depicted) BDI layer 250 and laterally adjacent to STI layer 240.

Backside ILD 610 may be composed of silicon dioxide, undoped silicate glass (USG), fluorosilicate glass (FSG), borophosphosilicate glass (BPSG), a spin-on low-K dielectric layer, a chemical vapor deposition (CVD) low-K dielectric layer or any combination thereof. The term “low-K” as used throughout the present application denotes a dielectric material that has a dielectric constant of less than silicon dioxide. In another embodiment, a self-planarizing material such as a spin-on glass (SOG) or a spin-on low-K dielectric material such as SiLK™ can be used as backside ILD 610. The use of a self-planarizing dielectric material as backside ILD 610 may avoid the need to perform a subsequent planarizing step.

In one embodiment, backside ILD 610 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as backside ILD 610, a planarization process or an etch back process follows the deposition of the dielectric material that provides backside ILD 610 such that the bottom surface of backside ILD 610 is coplanar with the bottom surface of STI layer 240.

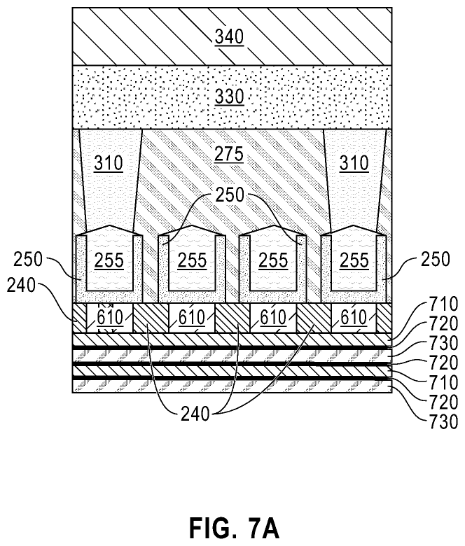

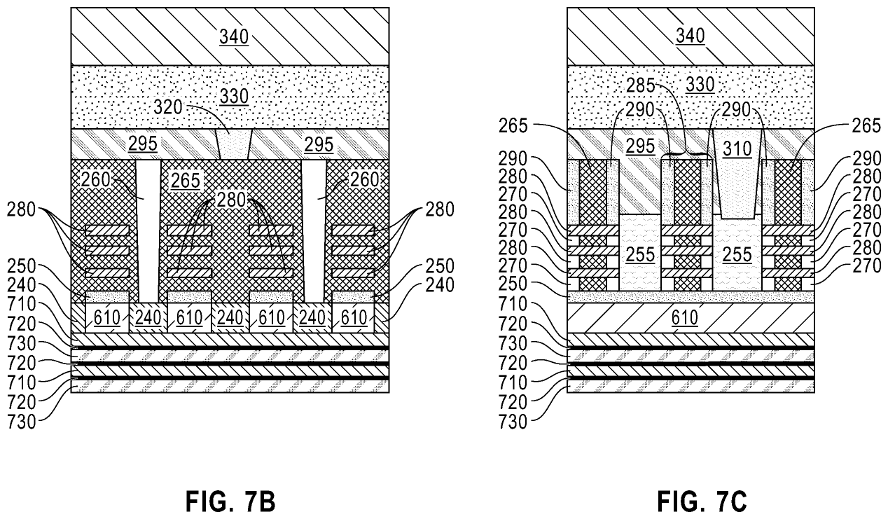

FIG. 7A depicts a cross-sectional view, of fabrication steps, along section line A of FIG. 1, FIG. 7B depicts a cross-sectional view along section line B of FIG. 1, and FIG. 7C depicts a cross-sectional view along section line C of FIG. 1. FIGS. 7A-7C depict the formation of a multiple layer MIM stack comprising, at least, layers of a first metal 710 and a second metal 730 separated by dielectric 720.

In general, the MIM stack will comprise alternating layers of first metal 710 and second metal 730, each later separated by dielectric 720. In the depicted embodiment, the MIM stack is composed of a first layer of first metal 710 beneath backside ILD 610, followed by in order, layers of dielectric 720, second metal 730, dielectric 720, first metal 710, dielectric 720, and second metal 730. Accordingly, the depicted embodiment includes a MIM stack comprising two layers of each of first metal 710 and second metal 730. In other embodiments, a larger or smaller (e.g., greater or fewer number of layers) MIM stack may be utilized.

Each layer of first metal 710, second metal 730, and dielectric 720 may be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

First metal 710 is, in general, a different metal than second metal 730. First metal 710 and second metal 730 may be composed of any metal, for example, an elemental metal (e.g., tungsten, titanium, tantalum, aluminum, nickel, ruthenium, palladium, TIN, TiAl, TiAlC, and platinum), an alloy of at least two elemental metals or multilayered combinations thereof.

Each layer of dielectric 720 may be an oxide, nitride, and/or oxynitride. In one example, dielectric 720 can be a high-k material having a dielectric constant greater than silicon dioxide. Example high-K dielectrics include, but are not limited to, HfO2, ZrO2, La2O3, Al2O3, TiO2, SrTiO3, LaAlO3, Y2O3, HfOxNy, ZrOxNy, La2OxNy, Al2OxNy, TiOxNy, SrTiOxNy, LaAlOxNy, Y2OxNy, SiON, SiNx, a silicate thereof, and an alloy thereof. Each value of x is independently from 0.5 to 3 and each value of y is independently from 0 to 2. In some embodiments, dielectric 720 can comprise different dielectric materials, e.g., silicon dioxide, and a high-k gate dielectric, can be formed and used as dielectric 720.

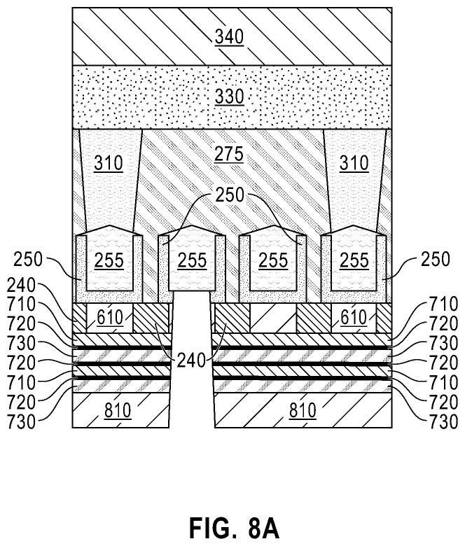

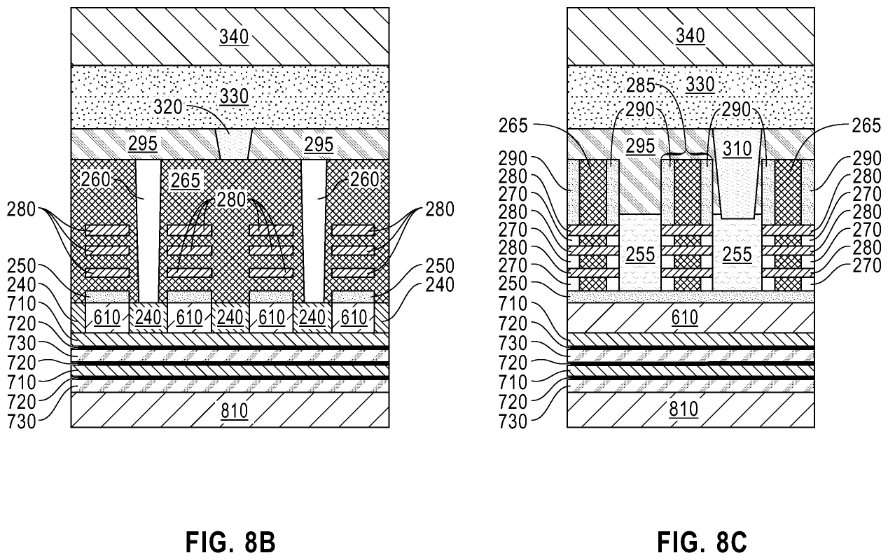

FIG. 8A depicts a cross-sectional view, of fabrication steps, along section line A of FIG. 1, FIG. 8B depicts a cross-sectional view along section line B of FIG. 1, and FIG. 8C depicts a cross-sectional view along section line C of FIG. 1. FIGS. 8A-8C depict the formation of backside ILD 810 and a backside contact trench formation for the nFET.

Backside ILD 810 material is formed below (as depicted) the MIM stack (as depicted, specifically below second metal 730).

Backside ILD 810 may be composed of silicon dioxide, undoped silicate glass (USG), fluorosilicate glass (FSG), borophosphosilicate glass (BPSG), a spin-on low-K dielectric layer, a chemical vapor deposition (CVD) low-K dielectric layer or any combination thereof. The term “low-K” as used throughout the present application denotes a dielectric material that has a dielectric constant of less than silicon dioxide. In another embodiment, a self-planarizing material such as a spin-on glass (SOG) or a spin-on low-K dielectric material such as SiLK™ can be used as backside ILD 810. The use of a self-planarizing dielectric material as backside ILD 810 may avoid the need to perform a subsequent planarizing step.

In one embodiment, backside ILD 810 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as backside ILD 810, a planarization process or an etch back process follows the deposition of the dielectric material that provides backside ILD 810.

A trench may be formed by an etching process such as RIE, laser ablation, or any etch process which can be used to selectively remove a portion of material such as backside ILD 810, second metal 730, dielectric 720, first metal 710, backside ILD 610, and BDI layer 250. A hardmask (not shown) may be patterned using photoresist to expose areas where trenches are desired and the hardmask may be utilized during the etching process in the creation of the trenches. The etching process only removes portions of the device not protected by the hardmask and the etching process stops at source/drain region 255.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

As depicted in FIG. 8A, the trench is formed with respect to the source/drain region 255 associated with the nFET that is not already contacted by S/D contacts 310.

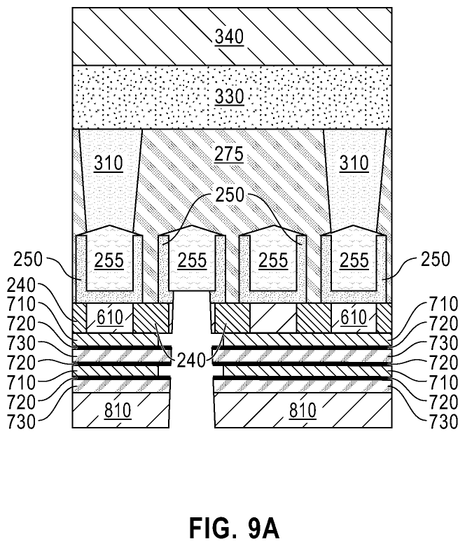

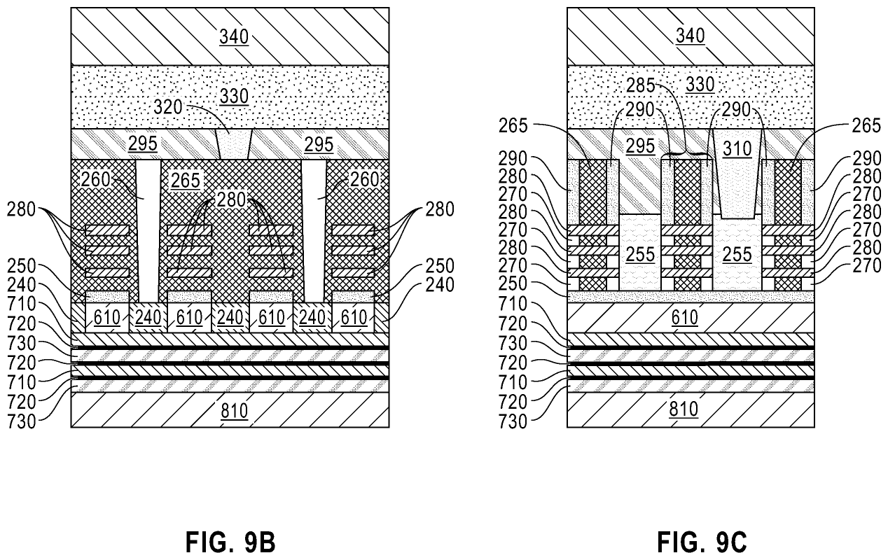

FIG. 9A depicts a cross-sectional view, of fabrication steps, along section line A of FIG. 1, FIG. 9B depicts a cross-sectional view along section line B of FIG. 1, and FIG. 9C depicts a cross-sectional view along section line C of FIG. 1. FIGS. 9A-9C depict the selective removal of portions of first metal 710.

Portions of first metal 710 may be removed by an etching process, such as RIE, wet etch, or any etch process which can be used to selectively etch first metal 710 relative to backside ILD 610, second metal 730, dielectric 720, and backside ILD 810.

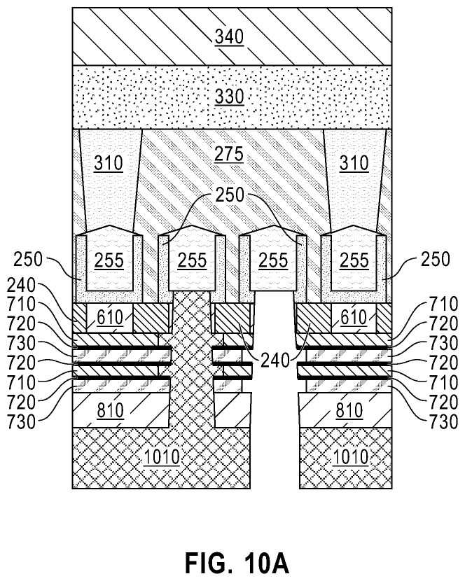

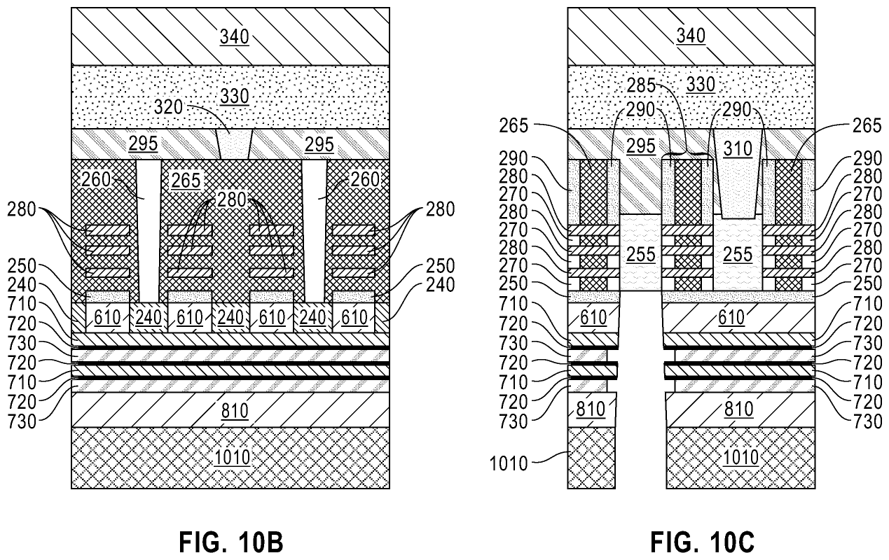

FIG. 10A depicts a cross-sectional view, of fabrication steps, along section line A of FIG. 1, FIG. 10B depicts a cross-sectional view along section line B of FIG. 1, and FIG. 10C depicts a cross-sectional view along section line C of FIG. 1. FIGS. 10A-10C depict the formation of organic planarization layer (OPL) 1010 and a backside contact trench formation for the pFET, followed by the removal of portions of second metal 730.

OPL 1010 can be a self-planarizing organic material that includes carbon, hydrogen, oxygen, and optionally nitrogen, fluorine, and silicon. In one embodiment, the self-planarizing organic material can be a polymer with sufficiently low viscosity so that the top surface of the applied polymer forms a planar horizontal surface. In one embodiment, OPL 1010 can include a transparent organic polymer. OPL 1010 can be a standard CₓH_{y} polymer.

OPL 1010 can be applied, for example, by spin-coating. In one embodiment, the thickness of OPL 1010 can be from about 30 nm to about 200 nm, although lesser and greater thicknesses can also be employed.

In one embodiment, OPL 1010 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as OPL 1010, a planarization process or an etch back process follows the deposition of the dielectric material that provides OPL 1010.

A trench may be formed by an etching process such as RIE, laser ablation, or any etch process which can be used to selectively remove a portion of material such as OPL 1010 backside ILD 810, second metal 730, dielectric 720, first metal 710, backside ILD 610, and BDI layer 250. A hardmask (not shown) may be patterned using photoresist to expose areas where trenches are desired and the hardmask may be utilized during the etching process in the creation of the trenches. The etching process only removes portions of the device not protected by the hardmask and the etching process stops at source/drain region 255.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

As depicted in FIGS. 10A and 10C, the trench is formed with respect to the source/drain region 255 associated with the pFET that is not already contacted by S/D contacts 310.

Subsequent to the formation of the backside contact trench for the pFET, portions of second metal 730 may be removed by an etching process, such as RIE, wet etch, or any etch process which can be used to selectively etch second metal 730 relative to OPL 1010, backside ILD 610, first metal 710, dielectric 720, and backside ILD 810.

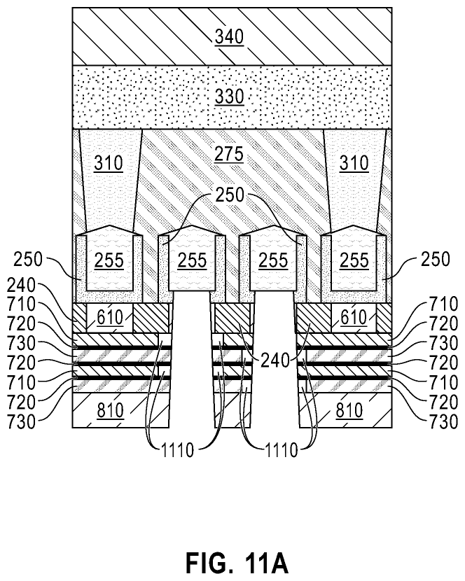

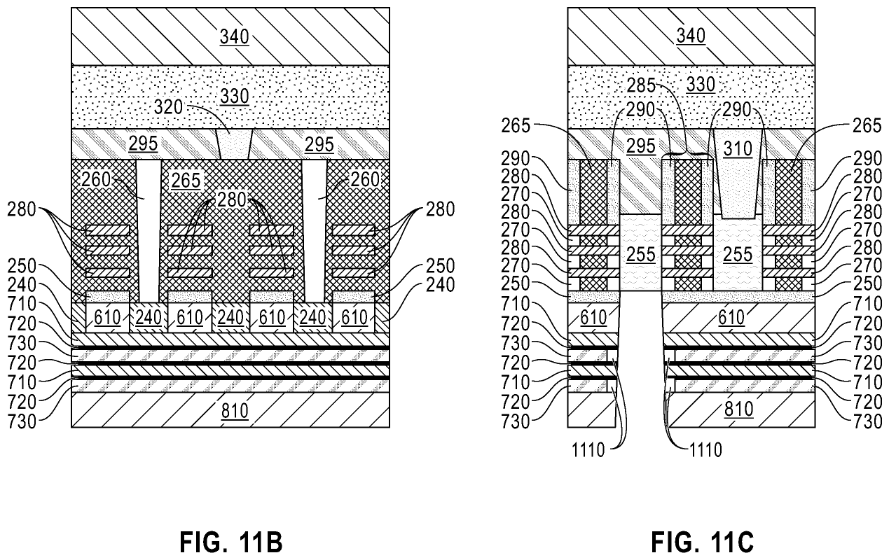

FIG. 11A depicts a cross-sectional view, of fabrication steps, along section line A of FIG. 1, FIG. 11B depicts a cross-sectional view along section line B of FIG. 1, and FIG. 11C depicts a cross-sectional view along section line C of FIG. 1. FIGS. 11A-11C depict the removal of OPL 1010 and formation of inner spacers 1110.

OPL 1010 may be removed, or stripped off, using, e.g., an ash process or wets removal.

Inner spacers 1110 may be formed in each of the recesses present within the contact trenches (e.g., recesses to first metal 710 and second metal 730). Inner spacers 1110 may be any dielectric spacer material. In on example, inner spacers 1110 are silicon nitride. Inner spacers 1110 are formed by a conformal dielectric liner deposition followed by isotropic etching back the deposited liner.

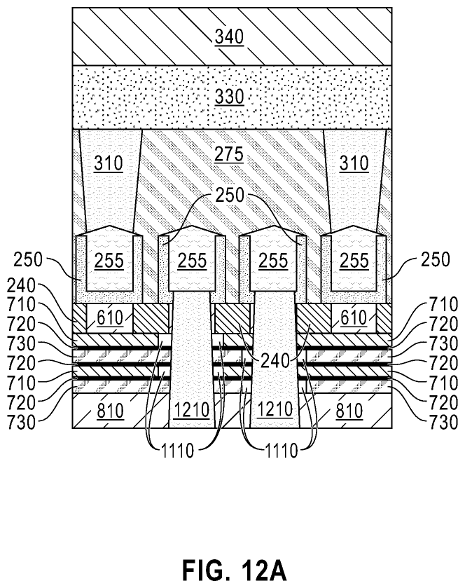

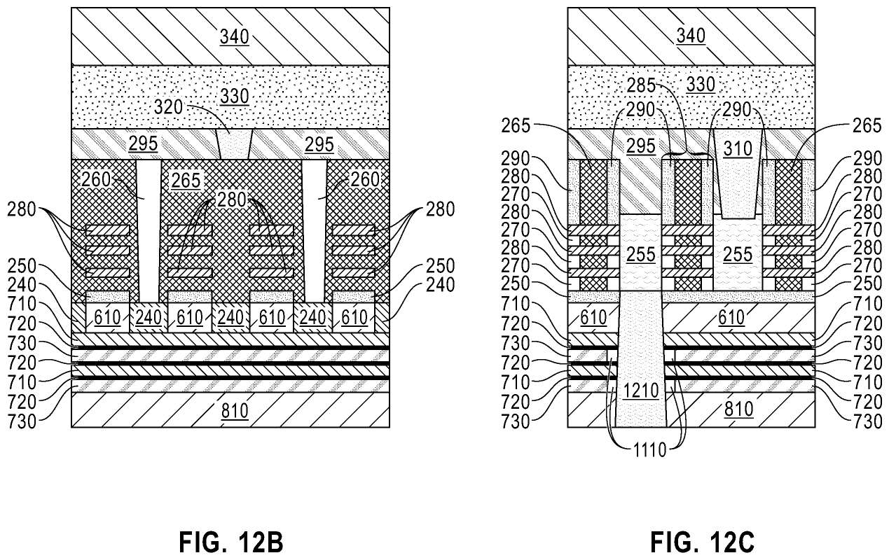

FIG. 12A depicts a cross-sectional view, of fabrication steps, along section line A of FIG. 1, FIG. 12B depicts a cross-sectional view along section line B of FIG. 1, and FIG. 12C depicts a cross-sectional view along section line C of FIG. 1. FIGS. 12A-12C depict the formation of backside contacts 1210.

In general, backside contacts 1210 are formed in the previously formed trenches (as discussed in reference to FIGS. 8A-8C though 11A-11C. Each backside contact 1210 makes contact with a source/drain 255.

Backside contacts 1210 may be formed by metal deposition and planarization. The metal layers comprise a silicide liner, such as, for example, Ti, Ni, or NiPt, followed by adhesion metal liner, such as, for example, TiN, and a conductive metal fill, such as, for example, Co, Ru, W, or Cu.

Each backside contact 1210 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

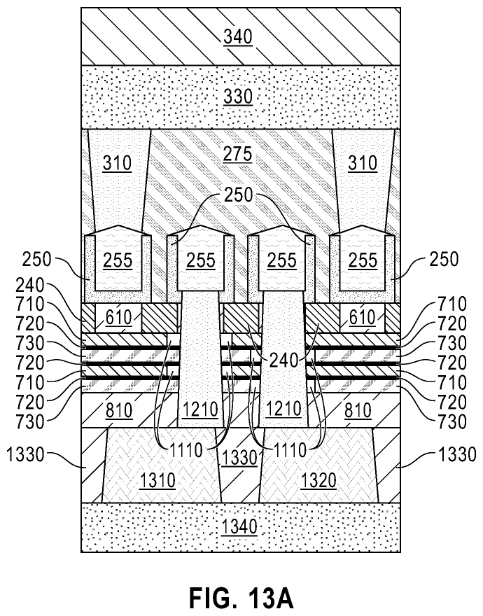

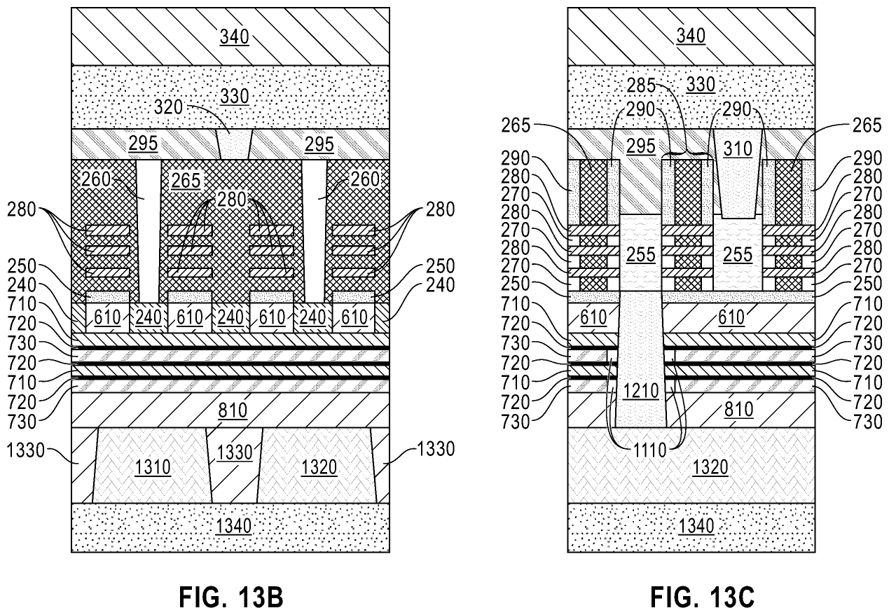

FIG. 13A depicts a cross-sectional view, of fabrication steps, along section line A of FIG. 1, FIG. 13B depicts a cross-sectional view along section line B of FIG. 1, and FIG. 13C depicts a cross-sectional view along section line C of FIG. 1. FIGS. 13A-13C depicts the formation of additional backside ILD 1330, V_{SS} backside power rail 1310, V_{DD} backside power rail 1320, and BSPDN 1340.

Backside ILD 1330 material is formed beneath (as depicted) backside ILD 810 and backside contacts 1210.

Backside ILD 1330 may be composed of silicon dioxide, undoped silicate glass (USG), fluorosilicate glass (FSG), borophosphosilicate glass (BPSG), a spin-on low-K dielectric layer, a chemical vapor deposition (CVD) low-K dielectric layer or any combination thereof. The term “low-K” as used throughout the present application denotes a dielectric material that has a dielectric constant of less than silicon dioxide. In another embodiment, a self-planarizing material such as a spin-on glass (SOG) or a spin-on low-K dielectric material such as SiLK™ can be used as backside ILD 1330. The use of a self-planarizing dielectric material as backside ILD 1330 may avoid the need to perform a subsequent planarizing step.

In one embodiment, backside ILD 1330 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as backside ILD 1330, a planarization process or an etch back process follows the deposition of the dielectric material that provides backside ILD 1330.

One or more trenches may be formed by an etching process, such as reactive-ion etching (RIE), laser ablation, or any etch process which can be used to remove a portion of material such as backside ILD 1330. A hardmask (not shown) may be patterned using photoresist to expose areas of backside ILD 1330 where trenches are desired and the hardmask may be utilized during the etching process in the creation of the trenches. The etching process only removes portions of backside ILD 1330 not protected by the hardmask, and the etching process stops at backside ILD 810 and backside contacts 1210.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

V_{SS} backside power rail 1310 and V_{DD} backside power rail 1320 may each be formed by, for example, depositing (e.g., by PVD), a metal layer (e.g., a thin adhesion TiN layer followed by bulk Cu, Co, or Ru fill) on exposed surfaces of backside contact 1210 and backside ILD 810. Any deposition process may be used for the formation of the metal layer including, for example, chemical vapor deposition (CVD), plasma enhanced chemical vapor deposition (PECVD), physical vapor deposition (PVD), plating, sputtering, or atomic layer deposition. In other embodiments, co-evaporation techniques may be utilized to form V_{SS} backside power rail 1310 and V_{DD} backside power rail 1320. In yet other embodiments, known sputter deposition or chemical vapor deposition techniques may be utilized to form the silicide layer.

In some embodiments, each of V_{SS} backside power rail 1310 and V_{DD} backside power rail 1320 are deposited such that V_{SS} backside power rail 1310 and/or V_{DD} backside power rail 1320 surrounds the silicide layer and fills the remaining area of the trench. V_{SS} backside power rail 1310 and V_{DD} backside power rail 1320 may each be in direct contact with the silicide layer, backside contact 1210, backside ILD 810, and backside ILD 1330.

V_{SS} backside power rail 1310 and V_{DD} backside power rail 1320 can each include a conductive material including, for example, Cu, Co, Ru, W with a thin adhesion liner such as, for example, TiN.

V_{SS} backside power rail 1310 and V_{DD} backside power rail 1320 can each be formed utilizing a deposition process including, for example, plating, chemical vapor deposition (CVD), plasma enhanced chemical vapor deposition (PECVD), physical vapor deposition (PVD), sputtering, atomic layer deposition (ALD) or other like deposition processes.

In general. V_{SS} backside power rail 1310 makes contact with a backside contact 1210 associated with the nFET of the device and V_{DD} backside power rail 1320 makes contact with a backside contact 1210 associated with the pFET of the device.

BSPDN 1340 comprises a backside power delivery network that is depicted as a simplified layer. BSPDN 1340 may be formed according to processes known in the art.

Subsequent to the formation of BSPDN 1340, the wafer may be released from carrier wafer 340 and flipped over (original flip which was discussed in reference to FIGS. 3A-3C was never depicted) such that BSPDN 1340 is on the bottom of the wafer and operates as a backside power delivery network. Alternatively, the carrier wafer 340 is kept, and through-silicon vias (TSVs) can be formed form backside of the wafer to BEOL interconnect at frontside.

The resulting semiconductor structure includes a backside MIM capacitor plane (first metal 710, dielectric 720, and second metal 730) underneath a logic region, where a first backside contact 1210 passes through the MIM capacitor plane (first metal 710, dielectric 720, and second metal 730), shorting the backside V_{SS} (V_{SS} backside power rail 1310), nFET source/drain epitaxy (source/drain 255), and first metal layers (first metal 710) of the MIM capacitor plane (first metal 710, dielectric 720, and second metal 730). A second backside contact 1210 passes through the MIM capacitor plane (first metal 710, dielectric 720, and second metal 730), shorting the backside V_{DD} (V_{DD} backside power rail 1320), pFET source/drain epitaxy (source/drain 255), and second metal layers (second metal 730) of the MIM capacitor plane (first metal 710, dielectric 720, and second metal 730). The first metal layers (first metal 710) and the second metal layers (second metal 730) are made of different metals. Inner spacers 1110 are formed at the sidewall of the direct backside contacts 1210 to isolate the nFET direct backside contact 1210 from the first metal layers (first metal 710) and to isolate the pFET direct backside contact 1210 from the second metal layers (second metal 730).

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first field-effect transistor (FET);
a second FET;
a metal-insulator-metal (MIM) capacitor plane beneath the first FET and the second FET, the MIM capacitor plane comprising a first metal layer and a second metal layer;
a backside power delivery network;
a first backside contact passing through the MIM capacitor plane, wherein the first backside contact is electrically insulated from the first metal layer; and
a second backside contact passing through the MIM capacitor plane, wherein the second backside contact is electrically insulated from the second metal layer.

2. The semiconductor structure of claim 1, wherein:
the first FET is a p-channel field-effect transistor (pFET); and
the second FET is an n-channel field-effect transistor (nFET).

3. The semiconductor structure of claim 1, wherein the first metal layer is a different type of metal than the second metal layer.

4. The semiconductor structure of claim 1, further comprising:
a dielectric spacer between the first backside contact and the first metal layer; and
a dielectric spacer between the second backside contact and the second metal layer.

5. The semiconductor structure of claim 2, wherein:
the first backside contact contacts a first source/drain region of the pFET; and
the second backside contact contacts a second source/drain region of the nFET.

6. The semiconductor structure of claim 5, further comprising:
a first backside power rail contacting the first backside contact; and
a second backside power rail contacting the second backside contact.

7. The semiconductor structure of claim 6, wherein:
the first backside power rail provides V_{DD} power delivery; and
the second backside power rail provides V_{SS} power delivery.

8. The semiconductor structure of claim 1, further comprising:
a backside interlayer dielectric (ILD) layer between the MIM capacitor plane and the backside power delivery network.

9. The semiconductor structure of claim 1, wherein the first FET is laterally adjacent to the second FET.

10. The semiconductor structure of claim 1, wherein the MIM capacitor plane further comprises a dielectric layer between the first metal layer and the second metal layer.

11. The semiconductor structure of claim 1, further comprising a dielectric layer between (i) the MIM capacitor plane and (ii) the first FET and the second FET.

12. A method of forming a semiconductor structure, the method comprising:
forming a first field-effect transistor (FET) and a second FET;
bonding a top surface of the semiconductor structure to a carrier wafer;
flipping the semiconductor structure;
forming a metal-insulator-metal (MIM) capacitor plane, the MIM capacitor plane comprising a first metal layer and a second metal layer;
forming a backside interlayer dielectric (ILD) layer on the MIM capacitor plane;
forming a first trench within the MIM capacitor plane and the backside ILD layer;
recessing exposed portions of the first metal layer within the first trench to create a first recess;
forming a second trench within the MIM capacitor plane and the backside ILD layer;
recessing exposed portions of the second metal layer within the second trench to create a second recess;
forming dielectric spacers in the first recess and the second recess; and
forming a first backside contact in the first trench and a second backside contact in the second trench.

13. The method of claim 12, further comprising:
subsequent to flipping the semiconductor structure, removing a semiconductor substrate.

14. The method of claim 12, further comprising:
prior to forming the second trench, forming an organic planarization layer (OPL) on a surface of the backside ILD layer and within the first trench; and
subsequent to recessing the exposed portions of the second metal layer, removing the OPL.

15. The method of claim 12, further comprising:
forming a first backside power rail contacting the first backside contact; and
forming a second backside power rail contacting the second backside contact.

16. The method of claim 12, further comprising:
forming a backside power delivery network.

17. The method of claim 12, wherein:
the first FET is a p-channel field-effect transistor (pFET); and
the second FET is an n-channel field-effect transistor (nFET).

18. The method of claim 12, wherein the first metal layer is a different type of metal than the second metal layer.

19. The method of claim 12, further comprising:
forming a back end of line (BEOL) interconnect; and
wherein bonding the top surface of the semiconductor structure to the carrier wafer comprises bonding the top surface of the BEOL interconnect to the carrier wafer.

20. A semiconductor structure comprising:
a first source/drain region and a second source/drain region;
a metal-insulator-metal (MIM) capacitor plane beneath the first source/drain region and the second source/drain region, the MIM capacitor plane comprising a first metal layer and a second metal layer;
a first backside contact passing through the MIM capacitor plane contacting the first source/drain region and the first metal layer; and
a second backside contact passing through the MIM capacitor plane contacting the second source/drain region and the second metal layer.
